(19) United States
(12) Patent Application Publication
(10) Pub. No.: US 2026/0293721 A1
(43) Pub. Date: Sep. 24, 2026

(54) PACKAGE COMPRISING A SUBSTRATE WITH IMPROVED VIA INTERCONNECT CONFIGURATION FOR IMPROVED THERMAL PERFORMANCE

(71) Applicant: QUALCOMM Incorporated, San Diego, CA (US)

(72) Inventors: Joan Rey Villarba BUOT, Escondido, CA (US); Kuiwon KANG, San Diego, CA (US); Hyun-Il MOON, Suwon-si (KR)

(21) Appl. No.: 19/085,799

(22) Filed: Mar. 20, 2025

(51) Int. Cl. H01L 23/538; H01L 23/00; H01L 23/498; H01L 25/18

(52) U.S. Cl. CPC H10W 70/65; H10W 70/611; H10W 90/00; H10W 90/401; H10W 90/701; H10W 90/724

(57) ABSTRACT

A package comprising a first substrate; a first integrated device coupled to the first substrate; a second substrate coupled to the first substrate through at least a plurality of solder interconnects, wherein the second substrate includes a plurality of interconnects comprising: a first plurality of interconnects comprising a first plurality of via interconnects, wherein at least one via interconnect from the first plurality of via interconnects comprises a first width; and a second plurality of interconnects comprising a second plurality of via interconnects, wherein at least one via interconnect from the second plurality of via interconnects comprises a second width that is different from the first width; an encapsulation layer located between the first substrate and the second substrate; and a second integrated device coupled to the second substrate.

### FIELD

Various features relate to packages with substrates and integrated devices.

### BACKGROUND

A package may include a substrate and integrated devices. These components are coupled together to provide a package that may perform various electrical functions. There is an ongoing need to provide better performing packages, including packages with improved thermal performances. There is also an ongoing need to reduce the overall size of the packages.

### SUMMARY

Various features relate to packages with substrates and integrated devices.

One example provides a package comprising a first substrate; a first integrated device coupled to the first substrate; a second substrate coupled to the first substrate through at least a plurality of solder interconnects, wherein the second substrate includes a plurality of interconnects comprising: a first plurality of interconnects comprising a first plurality of via interconnects, wherein at least one via interconnect from the first plurality of via interconnects comprises a first width; and a second plurality of interconnects comprising a second plurality of via interconnects, wherein at least one via interconnect from the second plurality of via interconnects comprises a second width that is different from the first width; an encapsulation layer located between the first substrate and the second substrate; and a second integrated device coupled to the second substrate.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes substrates and integrated devices.

FIG. 2 illustrates an exemplary cross sectional profile view of a package that includes substrates and integrated devices.

FIG. 3 illustrates an exemplary cross sectional plan view of a package that includes a substrate.

FIG. 4 illustrates an exemplary cross sectional plan view of a package that includes a substrate.

FIG. 5 illustrates an exemplary cross sectional plan view of a package that includes a substrate.

FIGS. 6A-6E illustrate an exemplary sequence for fabricating a package that includes substrates and integrated devices.

FIG. 7 illustrates an exemplary flow chart of a method for fabricating a package that includes substrates and integrated devices.

FIGS. 8A-8B illustrate an exemplary sequence for fabricating a substrate.

FIG. 9 illustrates an exemplary flow chart of a method for fabricating a substrate.

FIG. 10 illustrates an exemplary sequence for fabricating an interposer.

FIG. 11 illustrates an exemplary flow chart of a method for fabricating an interposer.

FIG. 12 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package comprising a first substrate; a first integrated device coupled to the first substrate; a second substrate coupled to the first substrate through at least a plurality of solder interconnects, wherein the second substrate includes a plurality of interconnects comprising: a first plurality of interconnects comprising a first plurality of via interconnects, wherein at least one via interconnect from the first plurality of via interconnects comprises a first width; and a second plurality of interconnects comprising a second plurality of via interconnects, wherein at least one via interconnect from the second plurality of via interconnects comprises a second width that is different from the first width; an encapsulation layer located between the first substrate and the second substrate; and a second integrated device coupled to the second substrate.

### Exemplary Package Comprising Substrates and Integrated Devices

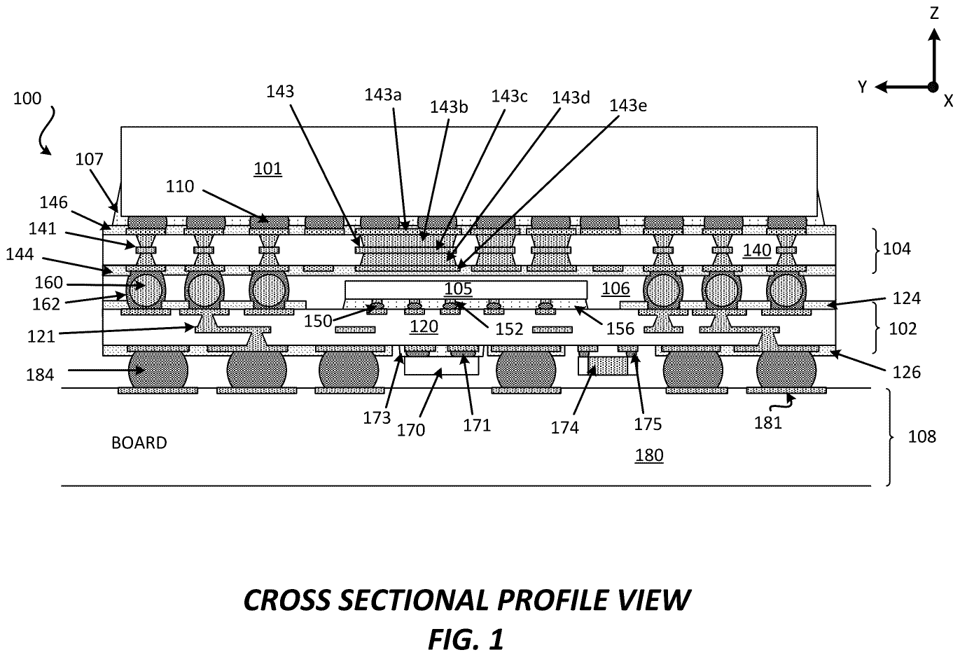

FIG. 1 illustrates a cross sectional profile view of a package 100 that may include substrates and integrated devices. The package 100 may be a package on package (PoP). The package 100 may be coupled to a board 108 through a plurality of solder interconnects 184. The board 108 may include at least one board dielectric layer 180 and a plurality of board interconnects 181. The board 108 may include a printed circuit board (PCB).

The package 100 may include an integrated device 101, a substrate 102, a substrate 104, an integrated device 105, an encapsulation layer 106, a plurality of core balls 160, a plurality of solder interconnects 162, a passive device 170, a passive device 174, an underfill 107, an underfill 156, and a plurality of solder interconnects 110.

The substrate 102 may include at least one dielectric layer 120, a plurality of interconnects 121, a solder resist layer 124 and a solder resist layer 126. The substrate 102 may be a coreless substrate. In some implementations, the at least one dielectric layer 120 may include prepreg and/or polyimide. However, different implementations may use different materials for the at least one dielectric layer 120. The substrate 102 may be coupled to the board 108 through the plurality of solder interconnects 184. The plurality of solder interconnects 184 may be coupled to the plurality of interconnects 121 and the plurality of board interconnects 181.

The substrate 104 may include at least one dielectric layer 140, a plurality of interconnects 141, a plurality of interconnects 143, a solder resist layer 144 and a solder resist layer 146. The plurality of interconnects 141 may be configured to provide electrical paths for input/output (I/O) signals. The plurality of interconnects 143 may be configured to provide electrical paths for ground. The plurality of interconnects 141 may include a plurality of pad interconnects, a plurality of via interconnects and/or a plurality of traces interconnects. The plurality of interconnects 143 may include a plurality of pad interconnects (e.g., landing pad interconnects), a plurality of via interconnects and/or a plurality of traces interconnects.

The substrate 104 may be coupled to the substrate 102 through the plurality of core balls 160 and/or the plurality of solder interconnects 162. The plurality of core balls 160 and/or the plurality of solder interconnects 162 may be coupled to and touch (i) the plurality of interconnects 121 of the substrate 102 and (ii) the plurality of interconnects 141 of the substrate 104. The plurality of core balls 160 may include a plurality of copper balls. The plurality of core balls 160 and/or the plurality of solder interconnects 162 may be located between the substrate 102 and the substrate 104. The plurality of core balls 160 may include a plurality of ball interconnects and/or core ball interconnects. The plurality of core balls 160 may include a plurality of copper balls. It is noted that one or more of the core balls from the plurality of core balls 160 do not need to be perfectly spherical in shape and/or form. In some implementations, the substrate 102 may be a first substrate and the substrate 104 may be a second substrate. In some implementations, the substrate 104 may be a first substrate and the substrate 102 may be a second substrate. In some implementations, the substrate 102 may be a different type of substrate from the substrate 104. In some implementations, the substrate 102 may be a similar type of substrate to the substrate 104. In some implementations, the substrate 102 may be a same type of substrate as the substrate 104.

The integrated device 105 may be coupled to a first surface (e.g., top surface) of the substrate 102. The integrated device 105 may be coupled to the substrate 102 through a plurality of pillar interconnects 152 and/or a plurality of solder interconnects 150. The plurality of solder interconnects 150 may be coupled to the plurality of interconnects 121 and the plurality of pillar interconnects 152. The underfill 156 may be located between the integrated device 105 and the substrate 102. The underfill 156 may at least partially encapsulate the plurality of pillar interconnects 152 and/or the plurality of solder interconnects 150. The integrated device 105 may be located between the substrate 102 and the substrate 104.

The encapsulation layer 106 is located between the substrate 102 and the substrate 104. The encapsulation layer 106 may include a mold, a resin, an epoxy and/or a filler. The encapsulation layer 106 may at least partially encapsulate the plurality of core balls 160, the plurality of solder interconnects 162, the integrated device 105 and/or the underfill 156. The encapsulation layer 106 may be provided by using a compression and transfer molding process, a sheet molding process, or a liquid molding process.

The passive device 170 may be coupled to a second surface (e.g., bottom surface) of the substrate 102. The passive device 170 may be coupled to the plurality of interconnects 121 of the substrate 102 through a plurality of solder interconnects 171. The passive device 170 may include a passive integrated device. An underfill 173 may be located between the passive device 170 and the substrate 102.

The passive device 174 may be coupled to a second surface (e.g., bottom surface) of the substrate 102. The passive device 174 may be coupled to the plurality of interconnects 121 of the substrate 102 through a plurality of solder interconnects 175. The passive device 174 may include a capacitor (e.g., surface mount capacitor).

The integrated device 101 is coupled to a first surface (e.g., top surface) of the substrate 104 through a plurality of solder interconnects 110. Some solder interconnects from the plurality of solder interconnects 110 may be coupled to the integrated device 101 and the plurality of interconnects 141. Some solder interconnects from the plurality of solder interconnects 110 may be coupled to the integrated device 101 and the plurality of interconnects 143. The plurality of interconnects 143 may be located vertically between the integrated device 101 and the integrated device 105. For example, via interconnects, trace interconnects and/or pad interconnects (e.g., landing pad interconnects) from the plurality of interconnects 143 may vertically overlap with the integrated device 101 and the integrated device 105. The plurality of interconnects 143 may be configured as a heat sink to dissipate heat from the integrated device 105. A landing pad interconnect may be a pad interconnect that is coupled to and touching a solder interconnect. The underfill 107 may be located between the integrated device 101 and the substrate 104.

The plurality of interconnects 141 may include at least one via interconnect that includes a first width (e.g., first via width). The plurality of interconnects 143 may include at least one via interconnect that includes a second width (e.g., second via width) that is different from the first width. In some implementations, the second width of the at least one via interconnect from the plurality of interconnects 143 may be greater than the first width of the at least one via interconnect from the plurality of interconnects 141. The plurality of interconnects 143 may include at least one other via interconnect that includes a third width (e.g., third via width) that is different from the first width and the second width. In some implementations, the third width of the at least one other via interconnect from the plurality of interconnects 143 may be greater than the first width of the at least one via interconnect from the plurality of interconnects 141. In some implementations, the third width of the at least one other via interconnect from the plurality of interconnects 143 may be greater than the second width of the at least one via interconnect from the plurality of interconnects 143.

The plurality of interconnects 143 may include one or more stacks of interconnects. For example, a stack of interconnects from the plurality of interconnects 143 may be define by two or more interconnects that vertically overlap each other. In some implementations, a stack of interconnects from the plurality of interconnects 143 may include an interconnect 143a, an interconnect 143b, an interconnect 143c, an interconnect 143d and/or an interconnect 143e. The interconnect 143a may include a pad interconnect (e.g., landing pad interconnect). The interconnect 143b may include a via interconnect. The interconnect 143c may include a pad interconnect. The interconnect 143d may include a via interconnect. The interconnect 143e may include a pad interconnect. The interconnect 143b may be coupled to and touch the interconnect 143a and the interconnect 143c. The interconnect 143d may be coupled to and touch the interconnect 143c and the interconnect 143e. A stack of interconnects may have different lateral sizes and/or shapes. As shown in FIG. 1, two or more solder interconnects from the plurality of solder interconnects 110 are coupled to and touch the interconnect 143a through two or more openings in the solder resist layer 146.

The plurality of interconnects 141 may include at least one landing pad interconnect that includes a first width (e.g., first landing pad width). The plurality of interconnects 143 may include at least one landing pad interconnect that includes a second width (e.g., second landing pad width) that is different from the first width. In some implementations, the second width of the at least one landing pad interconnect from the plurality of interconnects 143 may be greater than the first width of the at least one landing pad interconnect from the plurality of interconnects 141. The plurality of interconnects 143 may include at least one other landing pad interconnect that includes a third width (e.g., third landing pad width) that is different from the first width and the second width. In some implementations, the third width of the at least one other landing pad interconnect from the plurality of interconnects 143 may be greater than the first width of the at least one landing pad interconnect from the plurality of interconnects 141. In some implementations, the third width of the at least one other landing pad interconnect from the plurality of interconnects 143 may be greater than the second width of the at least one landing pad interconnect from the plurality of interconnects 143.

In some implementations, a landing pad interconnect from the plurality of interconnects 143 may have a width (e.g., landing pad width) that is at least 1.2 times greater than a width of a landing pad interconnect from the plurality of interconnects 141. In some implementations, a landing pad interconnect from the plurality of interconnects 143 may have a width (e.g., landing pad width) that is at least 1.5 times greater than a width of a landing pad interconnect from the plurality of interconnects 141. In some implementations, a landing pad interconnect from the plurality of interconnects 143 may have a width (e.g., landing pad width) that is at least 2 times greater than a width of a landing pad interconnect from the plurality of interconnects 141. In some implementations, a landing pad interconnect from the plurality of interconnects 143 may have a width (e.g., landing pad width) that is greater than a width of all landing pad interconnects from the plurality of interconnects 141.

In some implementations, a via interconnect from the plurality of interconnects 143 may have a width (e.g., via width) that is at least 1.2 times greater than a width of a via interconnect from the plurality of interconnects 141. In some implementations, a via interconnect from the plurality of interconnects 143 may have a width (e.g., via width) that is at least 1.5 times greater than a width of a via interconnect from the plurality of interconnects 141. In some implementations, a via interconnect from the plurality of interconnects 143 may have a width (e.g., via width) that is at least 2 times greater than a width of a via interconnect from the plurality of interconnects 141. In some implementations, a via interconnect from the plurality of interconnects 143 may have a width (e.g., via width) that is greater than a width of all via interconnects from the plurality of interconnects 141.

In some implementations, the use and/or location of the plurality of interconnects 143 provides improved heat dissipation capabilities for the package, which helps and improves the thermal performance of the package and/or the integrated devices(s). The improved thermal performance of the package and/or the integrated device(s) helps improve the overall performance of the package and/or the integrated device(s) while keeping the form factor of the package as small as possible.

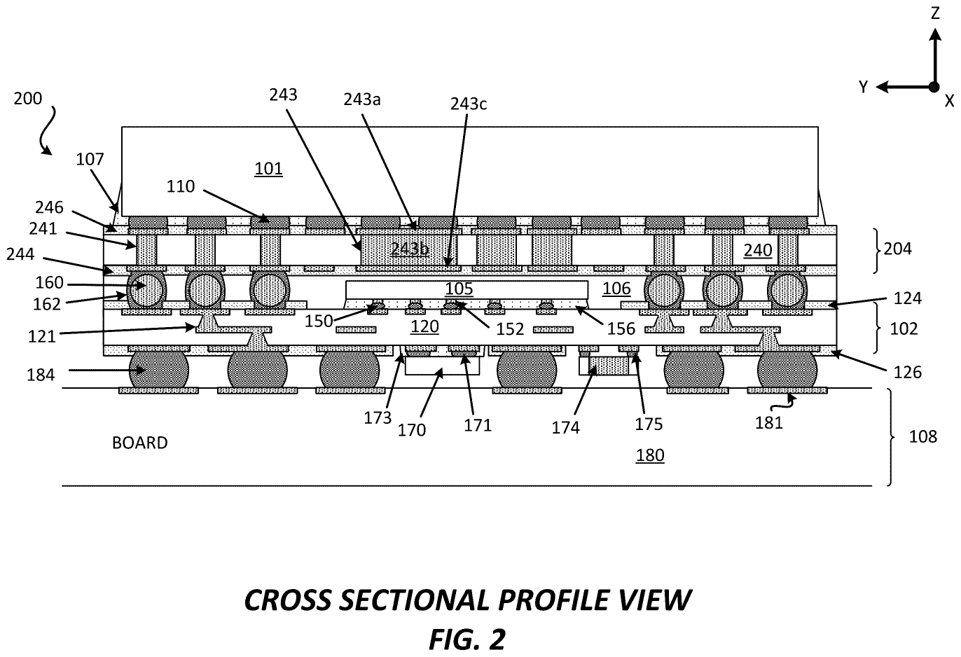

FIG. 2 illustrates a cross sectional profile view of a package 100 that may include substrates and integrated devices. The package 200 may be a package on package (PoP). The package 200 may be coupled to a board 108 through a plurality of solder interconnects 184. The board 108 may include at least one board dielectric layer 180 and a plurality of board interconnects 181. The board 108 may include a printed circuit board (PCB).

The package 200 may include an integrated device 101, a substrate 102, a substrate 204, an integrated device 105, an encapsulation layer 106, a plurality of core balls 160, a plurality of solder interconnects 162, a passive device 170, a passive device 174, an underfill 107, an underfill 156, and a plurality of solder interconnects 110. The package 200 is similar to the package 100. However, the package 200 includes a substrate 104. The substrate 104 may be an interposer (e.g., package interposer).

The substrate 102 may include at least one dielectric layer 120, a plurality of interconnects 121, a solder resist layer 124 and a solder resist layer 126. The substrate 102 may be a coreless substrate. In some implementations, the at least one dielectric layer 120 may include prepreg and/or polyimide. However, different implementations may use different materials for the at least one dielectric layer 120. The substrate 102 may be coupled to the board 108 through the plurality of solder interconnects 184. The plurality of solder interconnects 184 may be coupled to the plurality of interconnects 121 and the plurality of board interconnects 181.

The substrate 204 may include core layer 240, a plurality of interconnects 241, a plurality of interconnects 243, a solder resist layer 244 and a solder resist layer 246. The core layer 240 may include silicon (Si). The plurality of interconnects 241 may be configured to provide electrical paths for input/output (I/O) signals. The plurality of interconnects 243 may be configured to provide electrical paths for ground. The plurality of interconnects 241 may include a plurality of pad interconnects, a plurality of via interconnects and/or a plurality of traces interconnects. The plurality of interconnects 243 may include a plurality of pad interconnects (e.g., landing pad interconnects), a plurality of via interconnects and/or a plurality of traces interconnects.

The substrate 204 may be coupled to the substrate 102 through the plurality of core balls 160 and/or the plurality of solder interconnects 162. The plurality of core balls 160 and/or the plurality of solder interconnects 162 may be coupled to and touch (i) the plurality of interconnects 121 of the substrate 102 and (ii) the plurality of interconnects 141 of the substrate 204. The plurality of core balls 160 may include a plurality of copper balls. The plurality of core balls 160 and/or the plurality of solder interconnects 162 may be located between the substrate 102 and the substrate 204. The plurality of core balls 160 may include a plurality of ball interconnects and/or core ball interconnects. The plurality of core balls 160 may include a plurality of copper balls. It is noted that one or more of the core balls from the plurality of core balls 160 do not need to be perfectly spherical in shape and/or form. In some implementations, the substrate 102 may be a first substrate and the substrate 204 may be a second substrate. In some implementations, the substrate 204 may be a first substrate and the substrate 102 may be a second substrate. In some implementations, the substrate 102 may be a different type of substrate from the substrate 204. In some implementations, the substrate 102 may be a similar type of substrate to the substrate 204. In some implementations, the substrate 102 may be a same type of substrate as the substrate 204.

The integrated device 105 may be coupled to a first surface (e.g., top surface) of the substrate 102. The integrated device 105 may be coupled to the substrate 102 through a plurality of pillar interconnects 152 and/or a plurality of solder interconnects 150. The plurality of solder interconnects 150 may be coupled to the plurality of interconnects 121 and the plurality of pillar interconnects 152. The underfill 156 may be located between the integrated device 105 and the substrate 102. The underfill 156 may at least partially encapsulate the plurality of pillar interconnects 152 and/or the plurality of solder interconnects 150. The integrated device 105 may be located between the substrate 102 and the substrate 204.

The encapsulation layer 106 is located between the substrate 102 and the substrate 204. The encapsulation layer 106 may include a mold, a resin, an epoxy and/or a filler. The encapsulation layer 106 may at least partially encapsulate the plurality of core balls 160, the plurality of solder interconnects 162, the integrated device 105 and/or the underfill 156. The encapsulation layer 106 may be provided by using a compression and transfer molding process, a sheet molding process, or a liquid molding process.

The passive device 170 may be coupled to a second surface (e.g., bottom surface) of the substrate 102. The passive device 170 may be coupled to the plurality of interconnects 121 of the substrate 102 through a plurality of solder interconnects 171. The passive device 170 may include a passive integrated device. An underfill 173 may be located between the passive device 170 and the substrate 102.

The passive device 174 may be coupled to a second surface (e.g., bottom surface) of the substrate 102. The passive device 174 may be coupled to the plurality of interconnects 121 of the substrate 102 through a plurality of solder interconnects 175. The passive device 174 may include a capacitor (e.g., surface mount capacitor).

The integrated device 101 is coupled to a first surface (e.g., top surface) of the substrate 204 through a plurality of solder interconnects 110. Some solder interconnects from the plurality of solder interconnects 110 may be coupled to the integrated device 101 and the plurality of interconnects 241. Some solder interconnects from the plurality of solder interconnects 110 may be coupled to the integrated device 101 and the plurality of interconnects 243. The plurality of interconnects 243 may be located vertically between the integrated device 101 and the integrated device 105. For example, via interconnects, trace interconnects and/or pad interconnects (e.g., landing pad interconnects) from the plurality of interconnects 243 may vertically overlap with the integrated device 101 and the integrated device 105. The plurality of interconnects 243 may be configured as a heat sink to dissipate heat from the integrated device 105. The underfill 107 may be located between the integrated device 101 and the substrate 204.

The plurality of interconnects 241 may include at least one via interconnect that includes a first width (e.g., first via width). The plurality of interconnects 243 may include at least one via interconnect that includes a second width (e.g., second via width) that is different from the first width. In some implementations, the second width of the at least one via interconnect from the plurality of interconnects 243 may be greater than the first width of the at least one via interconnect from the plurality of interconnects 241. The plurality of interconnects 243 may include at least one other via interconnect that includes a third width (e.g., third via width) that is different from the first width and the second width. In some implementations, the third width of the at least one other via interconnect from the plurality of interconnects 243 may be greater than the first width of the at least one via interconnect from the plurality of interconnects 241. In some implementations, the third width of the at least one other via interconnect from the plurality of interconnects 243 may be greater than the second width of the at least one via interconnect from the plurality of interconnects 243.

The plurality of interconnects 243 may include may include an interconnect 243a, an interconnect 243b and/or an interconnect 243c. The interconnect 243a may include a pad interconnect (e.g., landing pad interconnect). The interconnect 243b may include a via interconnect. The interconnect 243c may include a pad interconnect. The interconnect 243b may be coupled to and touch the interconnect 243a and the interconnect 243c. As shown in FIG. 2, two or more solder interconnects from the plurality of solder interconnects 110 are coupled to and touch the interconnect 243a through two or more openings in the solder resist layer 246.

The plurality of interconnects 241 may include at least one landing pad interconnect that includes a first width (e.g., first landing pad width). The plurality of interconnects 243 may include at least one landing pad interconnect that includes a second width (e.g., second landing pad width) that is different from the first width. In some implementations, the second width of the at least one landing pad interconnect from the plurality of interconnects 243 may be greater than the first width of the at least one landing pad interconnect from the plurality of interconnects 241. The plurality of interconnects 243 may include at least one other landing pad interconnect that includes a third width (e.g., third landing pad width) that is different from the first width and the second width. In some implementations, the third width of the at least one other landing pad interconnect from the plurality of interconnects 243 may be greater than the first width of the at least one landing pad interconnect from the plurality of interconnects 241. In some implementations, the third width of the at least one other landing pad interconnect from the plurality of interconnects 243 may be greater than the second width of the at least one landing pad interconnect from the plurality of interconnects 243.

In some implementations, a landing pad interconnect from the plurality of interconnects 243 may have a width (e.g., landing pad width) that is at least 1.2 times greater than a width of a landing pad interconnect from the plurality of interconnects 241. In some implementations, a landing pad interconnect from the plurality of interconnects 243 may have a width (e.g., landing pad width) that is at least 1.5 times greater than a width of a landing pad interconnect from the plurality of interconnects 241. In some implementations, a landing pad interconnect from the plurality of interconnects 243 may have a width (e.g., landing pad width) that is at least 2 times greater than a width of a landing pad interconnect from the plurality of interconnects 241. In some implementations, a landing pad interconnect from the plurality of interconnects 243 may have a width (e.g., landing pad width) that is greater than a width of all landing pad interconnects from the plurality of interconnects 241.

In some implementations, a landing pad interconnect from the plurality of interconnects 243 may have a width (e.g., landing pad width) that is at least 1.2 times greater than a width of a landing pad interconnect from the plurality of interconnects 241. In some implementations, a landing pad interconnect from the plurality of interconnects 243 may have a width (e.g., landing pad width) that is at least 1.5 times greater than a width of a landing pad interconnect from the plurality of interconnects 241. In some implementations, a landing pad interconnect from the plurality of interconnects 243 may have a width (e.g., landing pad width) that is at least 2 times greater than a width of a landing pad interconnect from the plurality of interconnects 241. In some implementations, a via interconnect from the plurality of interconnects 243 may have a width (e.g., via width) that is greater than a width of all via interconnects from the plurality of interconnects 241.

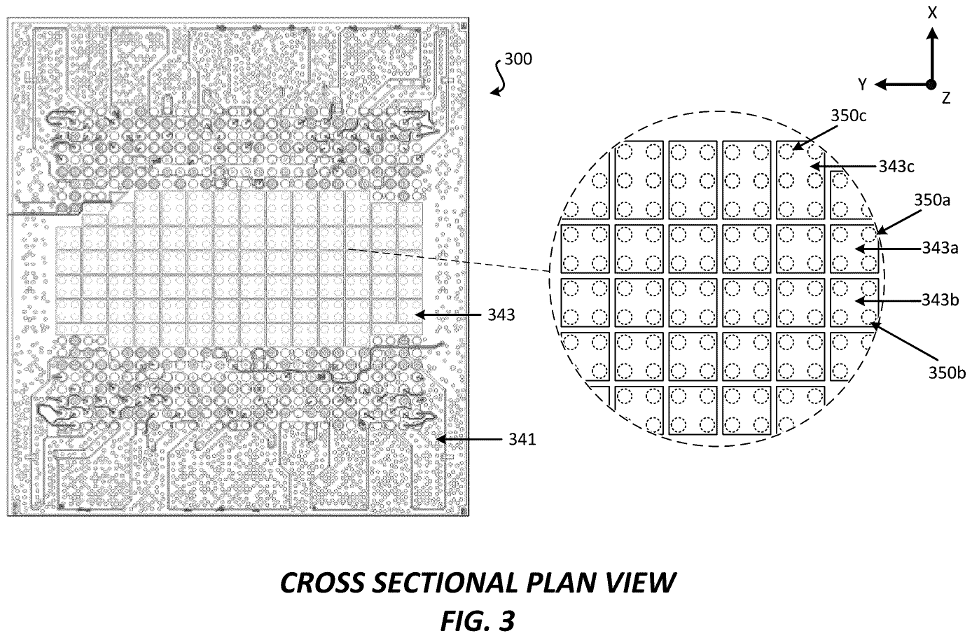

FIG. 3 illustrates an exemplary cross sectional plan view of substrate 300. The substrate 300 includes a plurality of interconnects 341 and a plurality of interconnects 343. In some implementations, the substrate 300 may represent the substrate 104, the plurality of interconnects 341 may represent the plurality of interconnects 141, and/or the plurality of interconnects 343 may represent the plurality of interconnects 143. In some implementations, the substrate 300 may represent the substrate 204, the plurality of interconnects 341 may represent the plurality of interconnects 241, and/or the plurality of interconnects 343 may represent the plurality of interconnects 243. The plurality of interconnects 341 may include trace interconnects, via interconnects and/or pad interconnects.

The plurality of interconnects 343 may vertically overlap with the integrated device 101 and the integrated device 105. The plurality of interconnects 343 may include interconnects that are arranged and/or configured in rows of interconnects. For example, the plurality of interconnects 343 may include via interconnects that are arranged and/or configured in rows of via interconnects. In some implementations, the plurality of interconnects 343 may include pad interconnects (e.g., landing pad interconnects) that are arranged and/or configured in rows of pad interconnects (e.g., landing pad interconnects). A row of interconnects may be defined in the Y direction and/or the X direction of an X-Y plane.

The plurality of interconnects 343 may include an interconnect 343a, an interconnect 343b and an interconnect 343c. In some implementations, the interconnect 343a, the interconnect 343b and the interconnect 343c may each represent a via interconnect. In some implementations, the interconnect 343a, the interconnect 343b and the interconnect 343c may each represent a landing pad interconnect. The substrate 300 includes a solder resist layer (e.g., 146) that includes a plurality of openings 350a, a plurality of openings 350b and a plurality of openings 350c. The plurality of openings 350a are located over the interconnect 343a. The plurality of openings 350b are located over the interconnect 343b. The plurality of openings 350c are located over the interconnect 343c. The plurality of openings 350a includes four openings in the solder resist layer through which four solder interconnects may be coupled to the interconnect 343a. The plurality of openings 350b includes four openings in the solder resist layer through which four solder interconnects may be coupled to the interconnect 343b. The plurality of openings 350c includes six openings in the solder resist layer through which six solder interconnects may be coupled to the interconnect 343c.

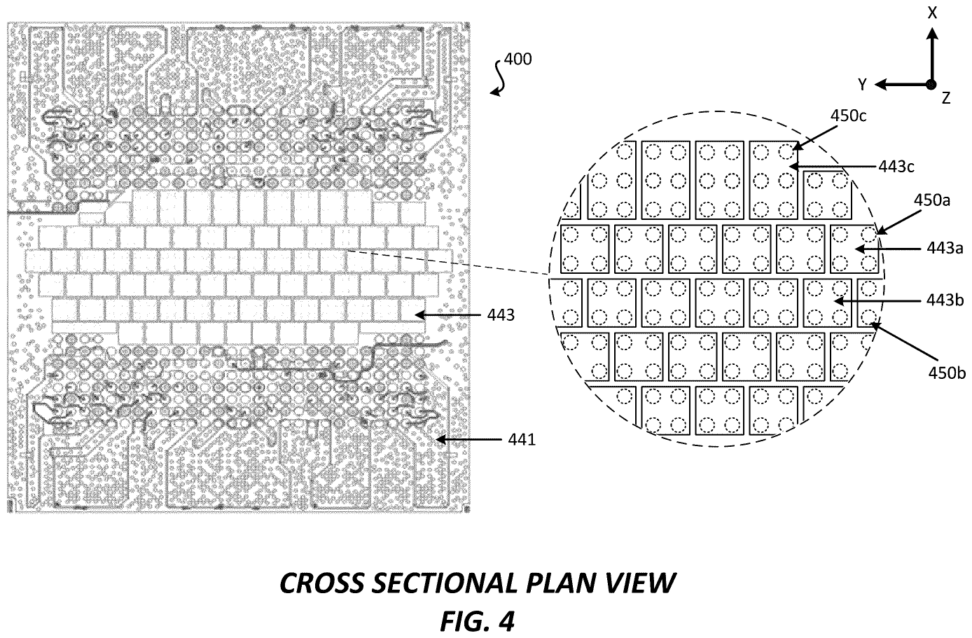

FIG. 4 illustrates an exemplary cross sectional plan view of substrate 400. The substrate 400 includes a plurality of interconnects 441 and a plurality of interconnects 443. In some implementations, the substrate 400 may represent the substrate 104, the plurality of interconnects 441 may represent the plurality of interconnects 141, and/or the plurality of interconnects 443 may represent the plurality of interconnects 143. In some implementations, the substrate 400 may represent the substrate 204, the plurality of interconnects 441 may represent the plurality of interconnects 241, and/or the plurality of interconnects 443 may represent the plurality of interconnects 243. The plurality of interconnects 441 may include trace interconnects, via interconnects and/or pad interconnects.

The plurality of interconnects 443 may vertically overlap with the integrated device 101 and the integrated device 105. The plurality of interconnects 443 may include interconnects that are arranged and/or configured in rows of interconnects. For example, the plurality of interconnects 443 may include via interconnects that are arranged and/or configured in staggered rows of via interconnects. In some implementations, the plurality of interconnects 443 may include pad interconnects (e.g., landing pad interconnects) that are arranged and/or configured in staggered rows of pad interconnects (e.g., landing pad interconnects). A row of interconnects may be defined in the Y direction and/or the X direction of an X-Y plane. FIG. 4 illustrates that in some implementations, two adjacent rows of interconnects may be staggered.

The plurality of interconnects 443 may include an interconnect 443a, an interconnect 443b and an interconnect 443c. In some implementations, the interconnect 443a, the interconnect 443b and the interconnect 443c may each represent a via interconnect. In some implementations, the interconnect 443a, the interconnect 443b and the interconnect 443c may each represent a landing pad interconnect. The substrate 400 includes a solder resist layer (e.g., 146) that includes a plurality of openings 450a, a plurality of openings 450b and a plurality of openings 450c. The plurality of openings 450a are located over the interconnect 443a. The plurality of openings 450b are located over the interconnect 443b. The plurality of openings 450c are located over the interconnect 443c. The plurality of openings 450a includes four openings in the solder resist layer through which four solder interconnects may be coupled to the interconnect 443a. The plurality of openings 450b includes four openings in the solder resist layer through which four solder interconnects may be coupled to the interconnect 443b. The plurality of openings 450c includes six openings in the solder resist layer through which six solder interconnects may be coupled to the interconnect 443c.

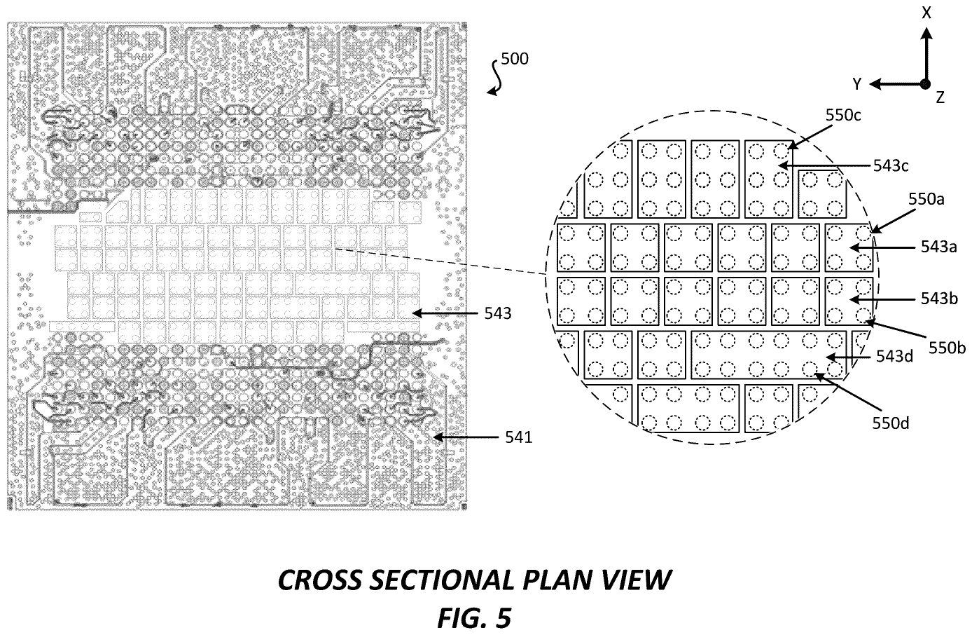

FIG. 5 illustrates an exemplary cross sectional plan view of substrate 500. The substrate 500 includes a plurality of interconnects 541 and a plurality of interconnects 543. In some implementations, the substrate 500 may represent the substrate 104, the plurality of interconnects 541 may represent the plurality of interconnects 141, and/or the plurality of interconnects 543 may represent the plurality of interconnects 143. In some implementations, the substrate 500 may represent the substrate 204, the plurality of interconnects 541 may represent the plurality of interconnects 241, and/or the plurality of interconnects 543 may represent the plurality of interconnects 243. The plurality of interconnects 541 may include trace interconnects, via interconnects and/or pad interconnects.

The plurality of interconnects 543 may vertically overlap with the integrated device 101 and the integrated device 105. The plurality of interconnects 543 may include interconnects that are arranged and/or configured in rows of interconnects. For example, the plurality of interconnects 543 may include via interconnects that are arranged and/or configured in rows of via interconnects and/or staggered rows of via interconnects. In some implementations, the plurality of interconnects 543 may include pad interconnects (e.g., landing pad interconnects) that are arranged and/or configured in rows of pad interconnects (e.g., landing pad interconnects) and/or staggered rows of pad interconnects (e.g., landing pad interconnects). A row of interconnects may be defined in the Y direction and/or the X direction of an X-Y plane. FIG. 5 illustrates that in some implementations, two adjacent rows of interconnects may be staggered. FIG. 5 also illustrates that in some implementations, two adjacent rows of interconnects may be aligned in the X direction and the Y direction of an X-Y plane.

The plurality of interconnects 543 may include an interconnect 543a, an interconnect 543b, an interconnect 543c and an interconnect 543d. In some implementations, the interconnect 543a, the interconnect 543b, the interconnect 543c and the interconnect 543d may each represent a via interconnect. In some implementations, the interconnect 543a, the interconnect 543b, the interconnect 543c and the interconnect 543d may each represent a landing pad interconnect. The substrate 500 includes a solder resist layer (e.g., 146) that includes a plurality of openings 550a, a plurality of openings 550b, a plurality of openings 550c and a plurality of openings 550d. The plurality of openings 550a are located over the interconnect 543a. The plurality of openings 550b are located over the interconnect 543b. The plurality of openings 550c are located over the interconnect 543c. The plurality of openings 550d are located over the interconnect 543d. The plurality of openings 550 a includes four openings in the solder resist layer through which four solder interconnects may be coupled to the interconnect 543a. The plurality of openings 550b includes four openings in the solder resist layer through which four solder interconnects may be coupled to the interconnect 543b. The plurality of openings 550c includes six openings in the solder resist layer through which six solder interconnects may be coupled to the interconnect 543c. The plurality of openings 550d includes twelve openings in the solder resist layer through which twelve solder interconnects may be coupled to the interconnect 543d.

FIGS. 3-5 illustrate examples of different configurations and/or arrangements of interconnects (e.g., 343, 443, 543). The interconnects may have different alignments, shapes and/or sizes. FIGS. 3-5 illustrate the plurality of interconnects (e.g., 343, 443, 543) has having a rectangular planar shape and/or a square planar shape. However, in some implementations, the plurality of interconnects (e.g., 343, 443, 543) may have other planar shapes (e.g., other non-rectangular shapes), such as a circular planar shape and/or a triangular planar shape. A planar shape may be a shape that is defined in the X-Y plane.

An integrated device (e.g., 101, 105) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc...). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one or more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 105) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap width between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100) may be implemented in a radio frequency (RF) package. The RF package may be a radio frequency front end (RFFE) package. A package (e.g., 100) may be configured to provide Wireless Fidelity (WiFi) communication and/or cellular communication (e.g., 2G, 3G, 4G, 5G, 6G). The packages (e.g., 100) may be configured to support Global System for Mobile (GSM) Communications, Universal Mobile Telecommunications System (UMTS), and/or Long-Term Evolution (LTE). The packages (e.g., 100) may be configured to transmit and receive signals having different frequencies and/or communication protocols.

### Exemplary Sequence for Fabricating a Package

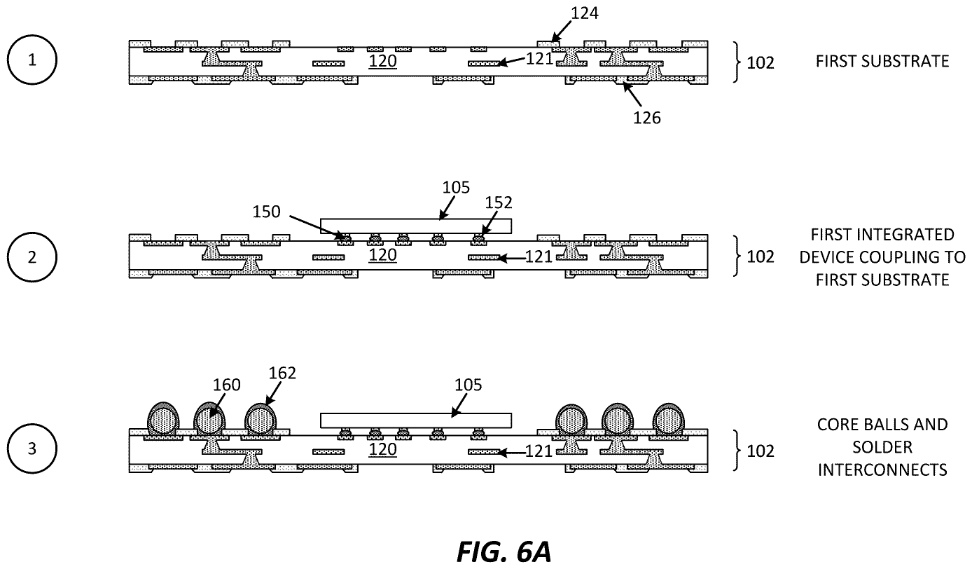

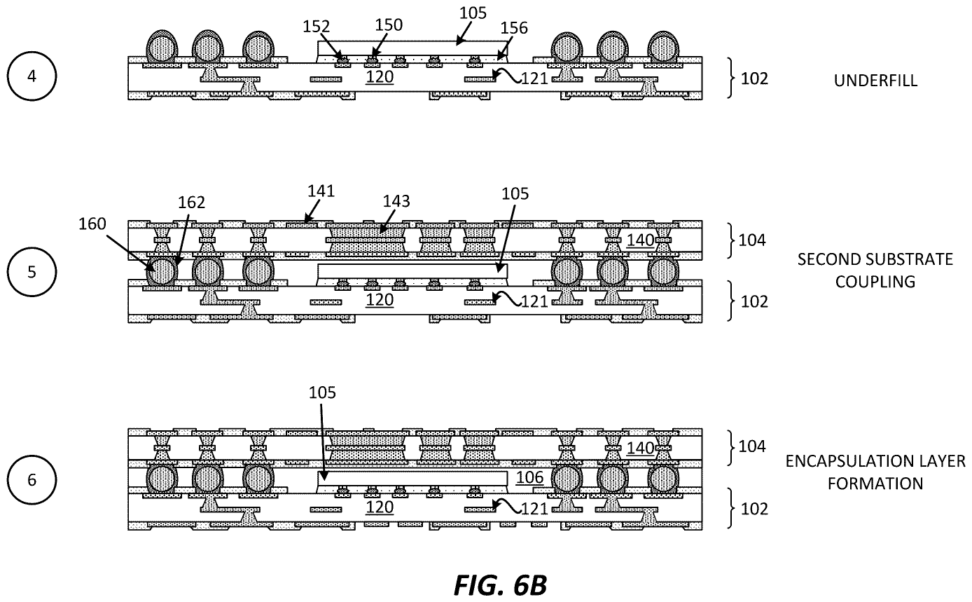

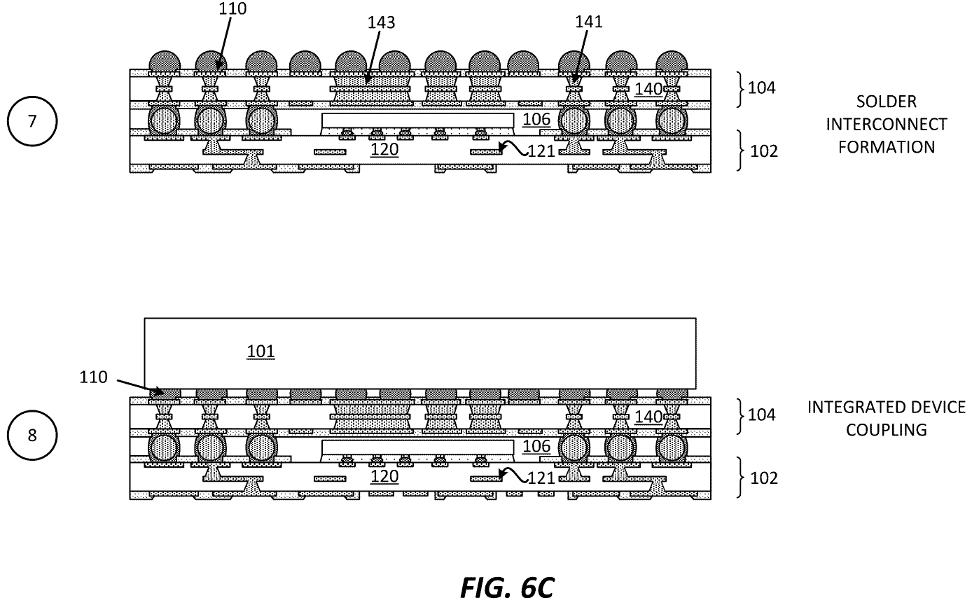

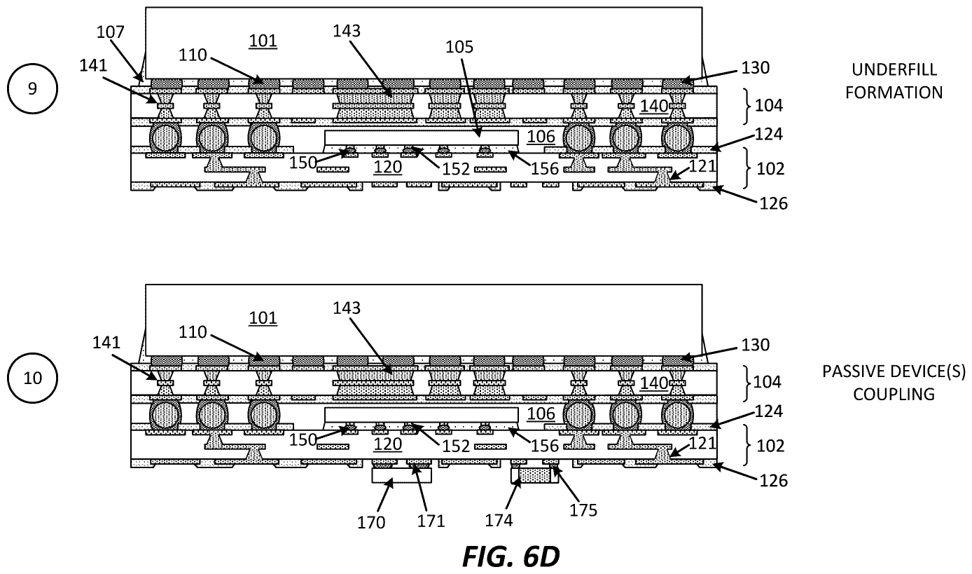

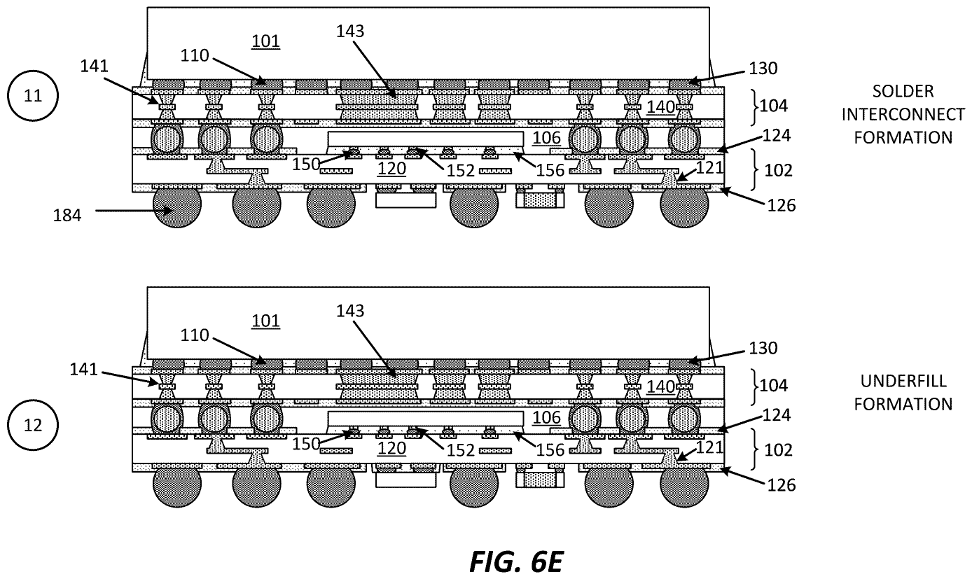

In some implementations, fabricating a package includes several processes. FIGS. 6A-6E illustrate an exemplary sequence for providing or fabricating a package. In some implementations, the sequence of FIGS. 6A-6E may be used to provide or fabricate the package 100. However, the process of FIGS. 6A-6E may be used to fabricate any of the packages (e.g., 200) described in the disclosure.

It should be noted that the sequence of FIGS. 6A-6E may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

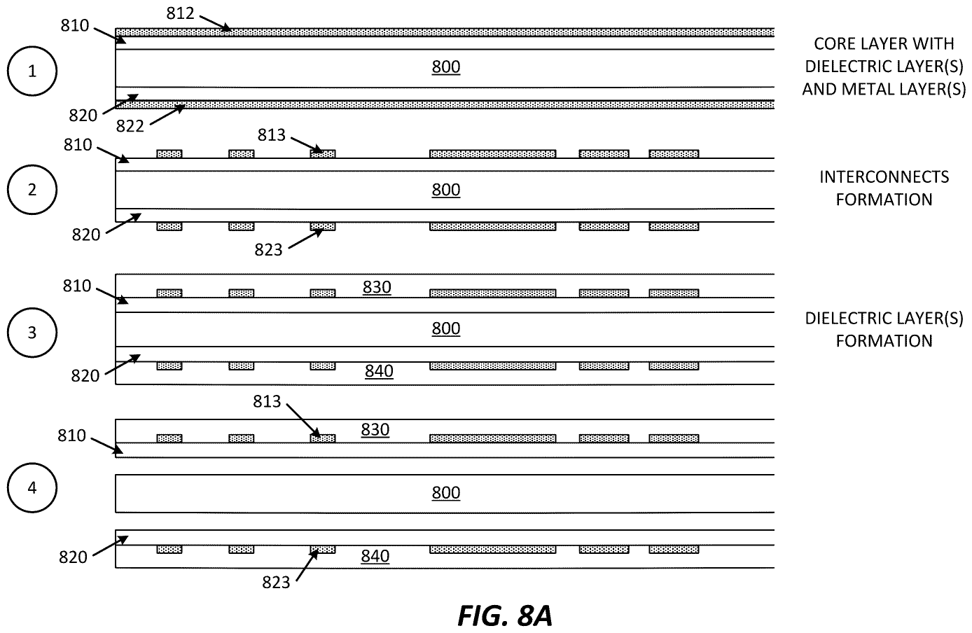

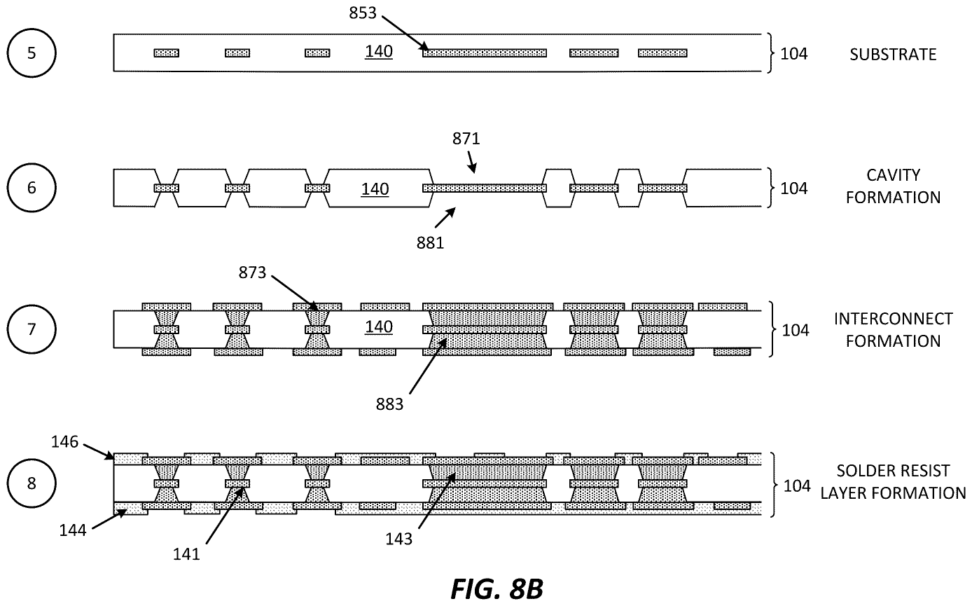

Stage 1, as shown in FIG. 6A, illustrates a state after a substrate 102 is provided. The substrate 102 includes at least one dielectric layer 120, a plurality of interconnects 121, a solder resist layer 124 and a solder resist layer 126. The substrate 102 may be a first substrate. The substrate 102 may include a first surface (e.g., top surface) and a second surface (e.g., bottom surface). The substrate 102 may be fabricated using the method as described in FIGS. 8A-8B.

Stage 2 illustrates a state after an integrated device 105 is coupled to the first surface (e.g., top surface) of the substrate 102. The integrated device 105 is coupled to the substrate 102 through the plurality of pillar interconnects 152 and a plurality of solder interconnects 150. A solder reflow process may be used to couple the integrated device 105 to the substrate 102.

Stage 3 illustrates a state after the plurality of core balls 160 and the plurality of solder interconnects 162 are coupled to the substrate 102. The plurality of core balls 160 and/or the plurality of solder interconnects 162 may be placed and/or dispensed on landing pad interconnects of the plurality of interconnects 121 of the substrate 102. In some implementations, a solder reflow process may be used on the plurality of core balls 160 and/or the plurality of solder interconnects 162 to the substrate 102.

Stage 4, as shown in FIG. 6B, illustrates a state after an underfill 156 is provided and/or formed between the integrated device 105 and the substrate 102. The underfill 156 may be dispensed between the integrated device 105 and the substrate 102. The underfill 156 may at least partially encapsulate the plurality of solder interconnects 150 and the plurality of pillar interconnects 152.

Stage 5 illustrates a state after the substrate 104 is provided and coupled to the substrate 102 through the plurality of core balls 160 and the plurality of solder interconnects 162. The substrate 104 may be a second substrate. The substrate 104 includes at least one dielectric layer 140, a plurality of interconnects 141, a plurality of interconnects 143, a solder resist layer 144 and a solder resist layer 146. A solder reflow process may be used to couple the substrate 104 to the substrate 102. The plurality of core balls 160 and/or the plurality of solder interconnects 162 may be coupled to and touch (i) landing pad interconnects of the plurality of interconnects 141 and/or (ii) landing pad interconnects of the plurality of interconnects 143. After the coupling of the substrate 104 to the substrate 102, the integrated device 105 may be located between the substrate 102 and the substrate 104. In some implementations, instead of the substrate 104, the substrate 204 may be coupled to the substrate 104 through the plurality of core balls 160 and the plurality of solder interconnects 162.

Stage 6 illustrates a state after the encapsulation layer 106 is provided between the substrate 102 and the substrate 104. The encapsulation layer 106 may include a mold, a resin, an epoxy and/or a filler. The encapsulation layer 106 may be a means for encapsulation. The encapsulation layer 106 may be provided by using a compression and transfer molding process, a sheet molding process, or a liquid molding process. The encapsulation layer 106 may at least partially encapsulate the integrated device 105, the underfill 156, the plurality of core balls 160 and/or the plurality of solder interconnects 162. The encapsulation layer 106 may include a different material from the underfill 156.

Stage 7, as shown in FIG. 6C, illustrates a state after a plurality of solder interconnects are formed and/or dispensed on the substrate 104. A pasting process may be used to form the plurality of solder interconnects. As shown at stage 7, the plurality of solder interconnects 110 may be formed and/or dispensed on the landing pad interconnects of the plurality of interconnects 141 of the substrate 104.

Stage 8 illustrates a state after the integrated device 101 is placed and coupled to the substrate 104 through a plurality of solder interconnects 110. A solder reflow process may be used to couple the integrated device 101to the substrate 104 through a plurality of solder interconnects 110. The integrated device 101 may be coupled to the plurality of interconnects 141 and the plurality of interconnects 143, through the plurality of solder interconnects 110.

Stage 9, as shown in FIG. 6D, illustrates a state after an underfill 107 is provided and/or dispensed. The underfill 107 may be located between the integrated device 101 and the substrate 104.

Stage 10 illustrates a state after the passive device 170 and the passive device 174 are coupled to a surface of the substrate 102 through a plurality of solder interconnects. A solder reflow process may be used to couple the passive device 170 and the passive device 174 to the substrate 102 through a plurality of solder interconnects. The passive device 170 may be coupled to landing pad interconnects of the plurality of interconnects 121 of the substrate 102 through a plurality of solder interconnects 171. The passive device 174 may be coupled to landing pad interconnects of the plurality of interconnects 121 of the substrate 102 through a plurality of solder interconnects 175.

Stage 11, as shown in FIG. 6E, illustrates a state after a plurality of solder interconnects 184 are coupled to the plurality of interconnects 121 of the substrate 102. A solder reflow process may be used to couple the plurality of solder interconnects 184 to landing pad interconnects of the plurality of interconnects 121.

Stage 12 illustrates a state after an underfill 173 is provided and/or dispensed. The underfill 173 may be located between the passive device 170 and the substrate 102. Stage 12 may illustrate the package 100 of FIG. 1.

### Exemplary Flow Diagram of a Method for Fabricating a Package

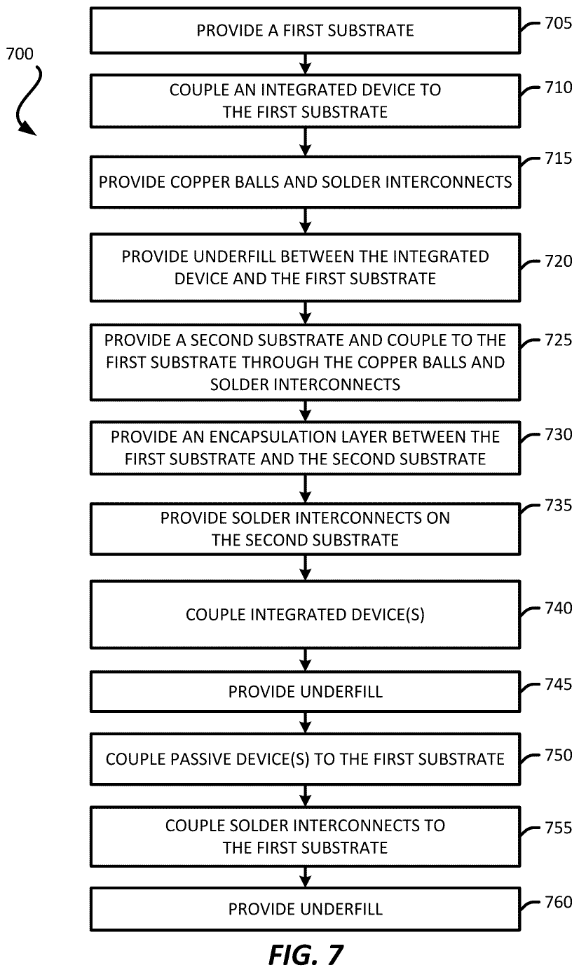

In some implementations, fabricating a package includes several processes. FIG. 7 illustrates an exemplary flow diagram of a method 700 for providing or fabricating a package. In some implementations, the method 700 of FIG. 7 may be used to provide or fabricate the package 100 described in the disclosure. However, the method 700 may be used to provide or fabricate any of the packages (e.g., 200) described in the disclosure.

It should be noted that the method 700 of FIG. 7 may combine one or more processes in order to simplify and/or clarify the method for providing or fabricating a package. In some implementations, the order of the processes may be changed or modified.

The method provides (at 705) a first substrate. Stage 1 of FIG. 6A, illustrates and describes an example of a state after a substrate 102 is provided. The substrate 102 includes at least one dielectric layer 120, a plurality of interconnects 121, a solder resist layer 124 and a solder resist layer 126. The substrate 102 may be a first substrate. The substrate 102 may include a first surface (e.g., top surface) and a second surface (e.g., bottom surface). The substrate 102 may be fabricated using the method as described in FIGS. 8A-8B.

The method couples (at 710) an integrated device to the first substrate. Stage 2 of FIG. 4A, illustrates and describes an example of a state after an integrated device 105 is coupled to the first surface (e.g., top surface) of the substrate 102. The integrated device 105 is coupled to the substrate 102 through the plurality of pillar interconnects 152 and a plurality of solder interconnects 150. A solder reflow process may be used to couple the integrated device 105 to the substrate 102.

The method provides and couples (at 715) a plurality of core balls and a plurality of solder interconnects to the first substrate. Stage 3 of FIG. 6A, illustrates and describes an example of a state after the plurality of core balls 160 and the plurality of solder interconnects 162 are coupled to the substrate 102. The plurality of core balls 160 and/or the plurality of solder interconnects 162 may be placed and/or dispensed on landing pad interconnects of the plurality of interconnects 121 of the substrate 102. In some implementations, a solder reflow process may be used on the plurality of core balls 160 and/or the plurality of solder interconnects 162.

The method provides (at 720) an underfill between the integrated device and the first substrate. Stage 4 of FIG. 6B, illustrates and describes an example of a state after an underfill 156 is provided and/or formed between the integrated device 105 and the substrate 102. The underfill 156 may be dispensed between the integrated device 105 and the substrate 102. The underfill 156 may at least partially encapsulate the plurality of solder interconnects 150 and the plurality of pillar interconnects 152.

The method provides and couples (at 725) a second substrate to the first substrate through the plurality of core balls and/or the plurality of solder interconnects.

Stage 5 of FIG. 6B, illustrates and describes an example of a state after the substrate 104 is provided and coupled to the substrate 102 through the plurality of core balls 160 and the plurality of solder interconnects 162. The substrate 104 may be a second substrate. The substrate 104 includes at least one dielectric layer 140, a plurality of interconnects 141, a plurality of interconnects 143, a solder resist layer 144 and a solder resist layer 146. A solder reflow process may be used to couple the substrate 104 to the substrate 102. The plurality of core balls 160 and/or the plurality of solder interconnects 162 may be coupled to and touch (i) landing pad interconnects of the plurality of interconnects 141 and/or (ii) landing pad interconnects of the plurality of interconnects 143. After the coupling of the substrate 104 to the substrate 102, the integrated device 105 may be located between the substrate 102 and the substrate 104. In some implementations, instead of the substrate 104, the substrate 204 may be coupled to the substrate 104 through the plurality of core balls 160 and the plurality of solder interconnects 162.

The method provides (at 730) an encapsulation layer between the first substrate and the second substrate. Stage 6 of FIG. 6B, illustrates and describes an example of a state after the encapsulation layer 106 is provided between the substrate 102 and the substrate 104. The encapsulation layer 106 may include a mold, a resin, an epoxy and/or a filler. The encapsulation layer 106 may be a means for encapsulation. The encapsulation layer 106 may be provided by using a compression and transfer molding process, a sheet molding process, or a liquid molding process. The encapsulation layer 106 may at least partially encapsulate the integrated device 105, the underfill 156, the plurality of core balls 160 and/or the plurality of solder interconnects 162.

The method provides and couples (at 735) a plurality of solder interconnects to the second substrate. Stage 7 of FIG. 6C, illustrates and describes an example of a state after a plurality of solder interconnects are formed and/or dispensed on the substrate 104. A pasting process may be used to form the plurality of solder interconnects. As shown at stage 7, the plurality of solder interconnects 110 may be formed and/or dispensed on the landing pad interconnects of the plurality of interconnects 141 of the substrate 104.

The method couples (at 740) an integrated device to the second substrate. Stage 8 of FIG. 6C, illustrates and describes an example of a state after the integrated device 101 is placed and coupled to the substrate 104 through a plurality of solder interconnects 110. A solder reflow process may be used to couple the integrated device 101to the substrate 104 through a plurality of solder interconnects 110. The integrated device 101 may be coupled to the plurality of interconnects 141 and the plurality of interconnects 143, through the plurality of solder interconnects 110.

The method provides (at 745) an underfill between the integrated devices and the second substrate. Stage 9 of FIG. 6D, illustrates and describes an example of a state after an underfill 107 is provided and/or dispensed. The underfill 107 may be located between the integrated device 101 and the substrate 104.

The method couples (at 750) at least one passive device to the first substrate. Stage 10 of FIG. 6D, illustrates and describes an example of a state after the passive device 170 and the passive device 174 are coupled to a surface of the substrate 102 through a plurality of solder interconnects. A solder reflow process may be used to couple the passive device 170 and the passive device 174 to the substrate 102 through a plurality of solder interconnects. The passive device 170 is coupled to landing pad interconnects of the plurality of interconnects 121 of the substrate 102 through a plurality of solder interconnects 171. The passive device 174 is coupled to landing pad interconnects of the plurality of interconnects 121 of the substrate 102 through a plurality of solder interconnects 175.

The method couples (at 755) a plurality of solder interconnects to the first substrate. Stage 11 of FIG. 6E, illustrates and describes an example of a state after a plurality of solder interconnects 184 are coupled to the plurality of interconnects 121 of the substrate 102. A solder reflow process may be used to couple the plurality of solder interconnects 184 to landing pad interconnects of the plurality of interconnects 121.

The method provides (at 760) an underfill between the first substrate and the passive device. Stage 12 of FIG. 6E, illustrates and describes an example of a state after an underfill 173 is provided and/or dispensed. The underfill 173 may be located between the passive device 170 and the substrate 102. Stage 12 of FIG. 6E may illustrate the package 100 of FIG. 1.

### Exemplary Sequence for Fabricating a Substrate

In some implementations, fabricating a substrate includes several processes. FIGS. 8A-8B illustrate an exemplary sequence for providing or fabricating a substrate. In some implementations, the sequence of FIGS. 8A-8B may be used to provide or fabricate a laminated substrate. The substrate that is fabricated in FIGS. 8A-8B may replace the substrate 104 of the disclosure.

It should be noted that the sequence of FIGS. 8A-8B may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 8A, illustrates a state after a core layer 800, a dielectric layer 810, a dielectric layer 820, a metal layer 812 and a metal layer 822 are provided. In some implementations, the core layer 800 may be provided and the dielectric layer 810 and the dielectric layer 820 are formed on the surfaces of the core layer 800. The metal layer 812 may then be formed on the dielectric layer 810 and the metal layer 822 may be formed on the dielectric layer 820. A lamination process and/or a deposition process may be used to form the dielectric layer 810 and/or the dielectric layer 820. The dielectric layer 810 and/or the dielectric layer 820 may include prepreg, polymer and/or Ajinomoto Build-up Film (ABF). A plating process may be used to form the metal layer 812 and/or the metal layer 822. In some implementations, the core layer 800 may include seed layer(s) on the surface(s) of the core layer 800.

Stage 2 illustrates a state after the plurality of interconnects 813 and the plurality of interconnects 823 are formed. The plurality of interconnects 813 may be formed from etching the metal layer 812. The plurality of interconnects 823 may be formed from etching the metal layer 822. A photo resist process (e.g., lamination, exposure, development), a plating process, a stripping process and/or an etching process may be used to form the plurality of interconnects 813 and/or the plurality of interconnects 823.

Stage 3 illustrates a state after a dielectric layer 830 and a dielectric layer 840 are formed. The dielectric layer 830 may be formed and coupled to the dielectric layer 810. The dielectric layer 840 may be formed and coupled to the dielectric layer 820. The dielectric layer 830 and/or the dielectric layer 840 may include prepreg, polymer and/or Ajinomoto Build-up Film (ABF).

Stage 4 illustrates a state after separation. After separation, the dielectric layer 810, the plurality of interconnects 813 and the dielectric layer 830 may be separated from the core layer 800. After separation, the dielectric layer 820, the plurality of interconnects 823 and the dielectric layer 840 may be separated from the core layer 800.

Stage 5, as shown in FIG. 8B, illustrates a substrate 104 that includes at least one dielectric layer 140 and a plurality of interconnects 853. In some implementations, the at least one dielectric layer 140 may represent the dielectric layer 810 and the dielectric layer 830. In some implementations, the plurality of interconnects 853 may represent the plurality of interconnects 813. In some implementations, the at least one dielectric layer 140 may represent the dielectric layer 820 and the dielectric layer 840. In some implementations, the plurality of interconnects 853 may represent the plurality of interconnects 823.

Stage 6 illustrates a state after a plurality of cavities 871 and a plurality of cavities 881 are formed. The plurality of cavities 871 may be formed through a top surface of the at least one dielectric layer 140. The plurality of cavities 881 may be formed through a bottom surface of the at least one dielectric layer 140. The plurality of cavities 871 may be formed with the plurality of cavities 881 to form a plurality of cavities. A laser process (e.g., laser ablation) and/or an etching process may be used to form the plurality of cavities 871 and/or plurality of cavities 881.

Stage 7 illustrates a state after a plurality of interconnects 873 and a plurality of interconnects 883 may be formed. The plurality of interconnects 873 may be coupled to interconnects from the plurality of interconnects 853. The plurality of interconnects 883 may be coupled to other interconnects from the plurality of interconnects 853. A photo resist process (e.g., lamination, exposure, development), a plating process, a stripping process and/or an etching process may be used to form the plurality of interconnects 873 and/or the plurality of interconnects 883. The plurality of interconnects 873 may represent the plurality of interconnects 141. The plurality of interconnects 883 may represent the plurality of interconnects 143.

Stage 8 illustrates a state after a solder resist layer 144 and a solder resist layer 146 are formed. The solder resist layer 144 may be formed and coupled to a bottom surface of the substrate 104. The solder resist layer 144 may include a plurality of openings. The solder resist layer 144 may be formed and coupled to a top surface of the substrate 104. The solder resist layer 146 may include a plurality of openings (e.g., 350a, 450a, 550a). A lamination process and/or a deposition process may be used to form the solder resist layer 144 and/or the solder resist layer 146.

### Exemplary Flow Diagram of a Method for Fabricating a Substrate

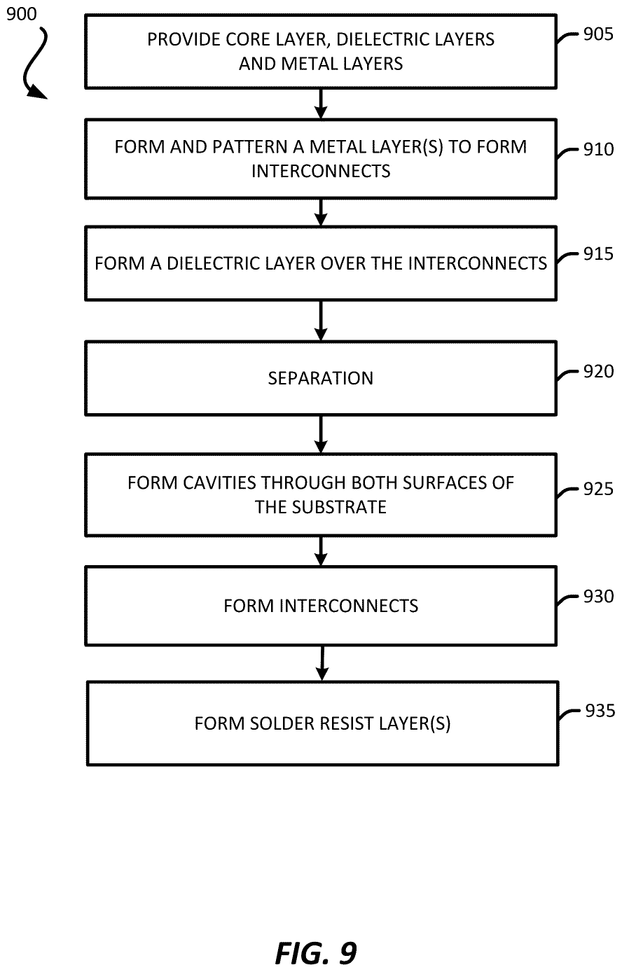

In some implementations, fabricating a substrate includes several processes. FIG. 9 illustrates an exemplary flow diagram of a method 900 for providing or fabricating a substrate. In some implementations, the method 900 of FIG. 9 may be used to provide or fabricate a substrate (e.g., 104).

It should be noted that the method 900 of FIG. 9 may combine one or more processes in order to simplify and/or clarify the method for providing or fabricating a substrate. In some implementations, the order of the processes may be changed or modified.

The method provides (at 905) a core layer, dielectric layers and metal layers. Stage 1 of FIG. 8A, illustrates and describes an example of a state after a core layer 800, a dielectric layer 810, a dielectric layer 820, a metal layer 812 and a metal layer 822 are provided. In some implementations, the core layer 800 may be provided and the dielectric layer 810 and the dielectric layer 820 are formed on the surfaces of the core layer 800. The metal layer 812 may then be formed on the dielectric layer 810 and the metal layer 822 may be formed on the dielectric layer 820. A lamination process and/or a deposition process may be used to form the dielectric layer 810 and/or the dielectric layer 820. The dielectric layer 810 and/or the dielectric layer 820 may include prepreg, polymer and/or Ajinomoto Build-up Film (ABF). A plating process may be used to form the metal layer 812 and/or the metal layer 822. In some implementations, the core layer 800 may include seed layer(s) on the surface(s) of the core layer 800.

The method forms and patterns (at 910) metal layers to form interconnects. Stage 2 of FIG. 8A, illustrates and describes an example of a state after the plurality of interconnects 813 and the plurality of interconnects 823 are formed. The plurality of interconnects 813 may be formed from etching the metal layer 812. The plurality of interconnects 823 may be formed from etching the metal layer 822. A photo resist process, a plating process, a stripping process and/or an etching process may be used to form the plurality of interconnects 813 and/or the plurality of interconnects 823.

The method forms (at 915) dielectric layers over interconnects. Stage 3 of FIG. 9A, illustrates and describes an example of a state after a dielectric layer 830 and a dielectric layer 840 are formed. The dielectric layer 830 may be formed and coupled to the dielectric layer 810. The dielectric layer 840 may be formed and coupled to the dielectric layer 820. The dielectric layer 830 and/or the dielectric layer 840 may include prepreg, polymer and/or Ajinomoto Build-up Film (ABF).

The method performs (at 920) separation. Stage 4 of FIG. 9A, illustrates and describes an example of a state after separation. After separation, the dielectric layer 810, the plurality of interconnects 813 and the dielectric layer 830 may be separated from the core layer 800. After separation, the dielectric layer 820, the plurality of interconnects 823 and the dielectric layer 840 may be separated from the core layer 800.

Stage 5 of FIG. 9B, illustrates a substrate 104 that includes at least one dielectric layer 140 and a plurality of interconnects 853. In some implementations, the at least one dielectric layer 140 may represent the dielectric layer 810 and the dielectric layer 830. In some implementations, the plurality of interconnects 853 may represent the plurality of interconnects 813. In some implementations, the at least one dielectric layer 140 may represent the dielectric layer 820 and the dielectric layer 840. In some implementations, the plurality of interconnects 853 may represent the plurality of interconnects 823.

The method forms (at 925) a plurality of cavities in the at least one dielectric layer. Stage 6 of FIG. 9B, illustrates and describes an example of a state after a plurality of cavities 871 and a plurality of cavities 881 are formed. The plurality of cavities 871 may be formed through a top surface of the at least one dielectric layer 140. The plurality of cavities 881 may be formed through a bottom surface of the at least one dielectric layer 140. The plurality of cavities 871 may be formed with the plurality of cavities 881 to form a plurality of cavities. A laser process (e.g., laser ablation) and/or an etching process may be used to form the plurality of cavities 871 and/or plurality of cavities 881.

The method forms (at 930) a plurality of interconnects. Stage 7 of FIG. 9B, illustrates and describes an example of a state after a plurality of interconnects 873 and a plurality of interconnects 883 may be formed. The plurality of interconnects 873 may be coupled to interconnects from the plurality of interconnects 853. The plurality of interconnects 883 may be coupled to other interconnects from the plurality of interconnects 853. A photo resist process (e.g., lamination, exposure, development), a plating process, a stripping process and/or an etching process may be used to form the plurality of interconnects 873 and/or the plurality of interconnects 883. The plurality of interconnects 873 may represent the plurality of interconnects 141. The plurality of interconnects 883 may represent the plurality of interconnects 143.

The method forms (at 935) at least one solder resist layer. Stage 8 of FIG. 8B, illustrates and describes an example of a state after a solder resist layer 144 and a solder resist layer 146 are formed. The solder resist layer 144 may be formed and coupled to a bottom surface of the substrate 104. The solder resist layer 144 may include a plurality of openings. The solder resist layer 144 may be formed and coupled to a top surface of the substrate 104. The solder resist layer 146 may include a plurality of openings (e.g., 350a, 450a, 550a). A lamination process and/or a deposition process may be used to form the solder resist layer 144 and/or the solder resist layer 146.

### Exemplary Sequence for Fabricating a Substrate

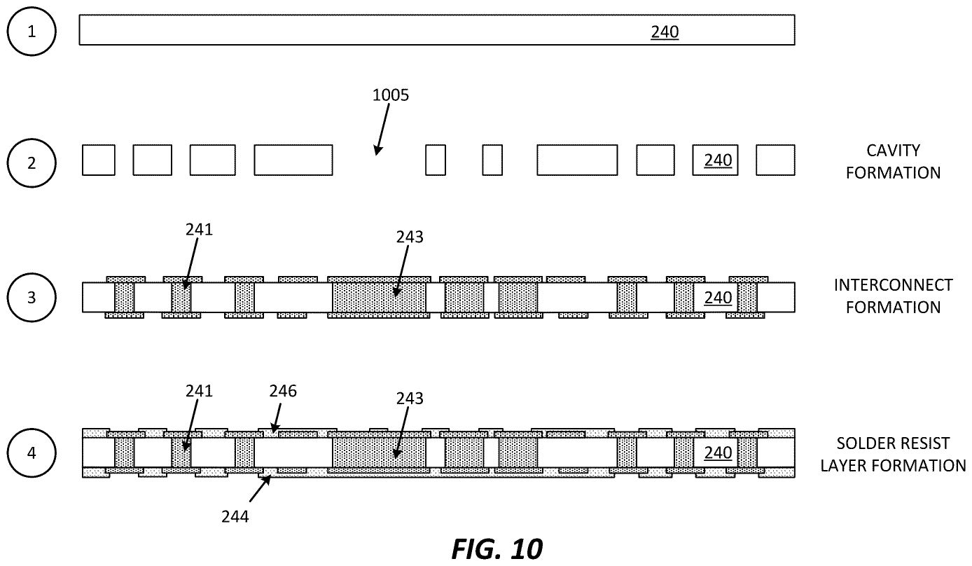

In some implementations, fabricating a substrate includes several processes. FIG. 10 illustrate an exemplary sequence for providing or fabricating a substrate. In some implementations, the sequence of FIG. 10 may be used to provide or fabricate a laminated substrate. The substrate that is fabricated in FIG. 10 may replace the substrate 204 of the disclosure.

It should be noted that the sequence of FIG. 10 may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 10, illustrates a state after a core layer 240 is provided. In some implementations, the core layer 240 may include seed layer(s) on the surface(s) of the core layer 240. The core layer 240 may include silicon (Si) or glass.

Stage 2 illustrates a state after a plurality of cavities 1005 are formed. The plurality of cavities 871 may be formed through a top surface and/or a bottom surface of the core layer 240. The plurality of cavities 881 may be formed through a bottom surface of the at least one dielectric layer 140. The plurality of cavities 871 may be formed with the plurality of cavities 881 to form a plurality of cavities. A laser process (e.g., laser ablation) and/or an etching process may be used to form the plurality of cavities 871 and/or plurality of cavities 881.

Stage 3 illustrates a state after a plurality of interconnects 241 and a plurality of interconnects 243 may be formed. A photo resist process (e.g., lamination, exposure, development), a plating process, a stripping process and/or an etching process may be used to form the plurality of interconnects 241 and/or the plurality of interconnects 243.

Stage 4 illustrates a state after a solder resist layer 244 and a solder resist layer 246 are formed. The solder resist layer 244 may be formed and coupled to a bottom surface of the substrate 204. The solder resist layer 244 may include a plurality of openings. The solder resist layer 244 may be formed and coupled to a top surface of the substrate 204. The solder resist layer 246 may include a plurality of openings (e.g., 350a, 450a, 550a). A lamination process and/or a deposition process may be used to form the solder resist layer 144 and/or the solder resist layer 146.

### Exemplary Flow Diagram of a Method for Fabricating a Substrate

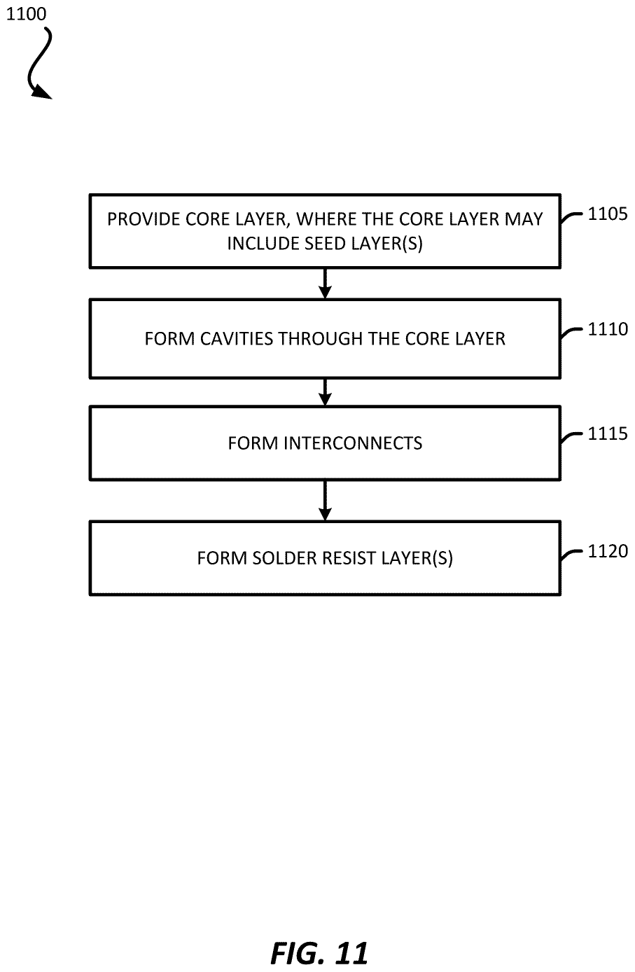

In some implementations, fabricating a substrate includes several processes. FIG. 11 illustrates an exemplary flow diagram of a method 1100 for providing or fabricating a substrate. In some implementations, the method 1100 of FIG. 11 may be used to provide or fabricate a substrate (e.g., 204).

It should be noted that the method 1100 of FIG. 11 may combine one or more processes in order to simplify and/or clarify the method for providing or fabricating a substrate. In some implementations, the order of the processes may be changed or modified.

The method provides (at 1105) a core layer. The core layer may include seed layer(s). Stage 1 of FIG. 10, illustrates and describes an example of a state after a core layer 240 is provided. In some implementations, the core layer 240 may include seed layer(s) on the surface(s) of the core layer 240. The core layer 240 may include silicon (Si) or glass.

The method forms (at 1110) a plurality of cavities in the core layer. Stage 2 illustrates and describes an example of a state after a plurality of cavities 1005 are formed. The plurality of cavities 871 may be formed through a top surface and/or a bottom surface of the core layer 240. The plurality of cavities 881 may be formed through a bottom surface of the at least one dielectric layer 140. The plurality of cavities 871 may be formed with the plurality of cavities 881 to form a plurality of cavities. A laser process (e.g., laser ablation) and/or an etching process may be used to form the plurality of cavities 871 and/or plurality of cavities 881.

The method forms (at 1115) a plurality of interconnects. Stage 3 illustrates and describes an example of a state after a plurality of interconnects 241 and a plurality of interconnects 243 may be formed. A photo resist process (e.g., lamination, exposure, development), a plating process, a stripping process and/or an etching process may be used to form the plurality of interconnects 241 and/or the plurality of interconnects 243.

The method forms (at 1120) at least one solder resist layer. Stage 4 illustrates and describes an example of a state after a solder resist layer 244 and a solder resist layer 246 are formed. The solder resist layer 244 may be formed and coupled to a bottom surface of the substrate 204. The solder resist layer 244 may include a plurality of openings. The solder resist layer 244 may be formed and coupled to a top surface of the substrate 204. The solder resist layer 246 may include a plurality of openings (e.g., 350a, 450a, 550a). A lamination process and/or a deposition process may be used to form the solder resist layer 144 and/or the solder resist layer 146.

Exemplary Electronic Devices

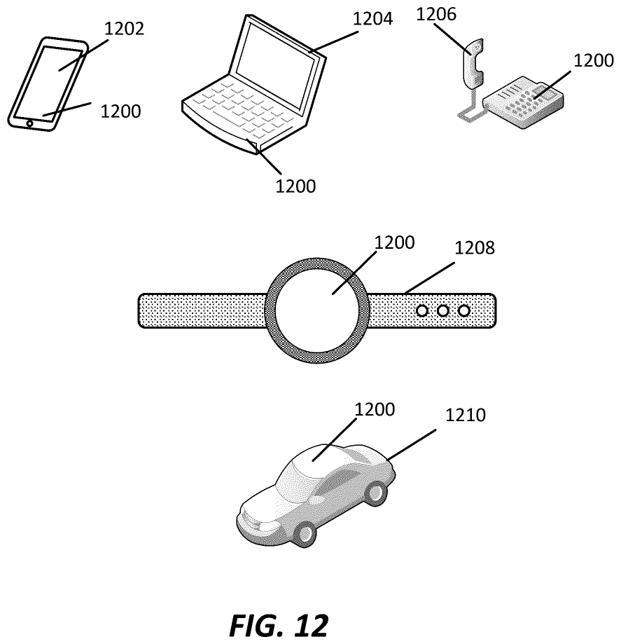

FIG. 12 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1202, a laptop computer device 1204, a fixed location terminal device 1206, a wearable device 1208, or automotive vehicle 1210 may include a device 1200 as described herein. The device 1200 may be, for example, any of the devices and/or integrated circuit (IC) packages described herein. The devices 1202, 1204, 1206 and 1208 and the vehicle 1210 illustrated in FIG. 12 are merely exemplary. Other electronic devices may also feature the device 1200 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-5, 6A-6E, 7, 8A-8B and 9-12 may be rearranged and/or combined into a single component, process, feature or function or embodied in several components, processes, or functions. Additional elements, components, processes, and/or functions may also be added without departing from the disclosure. It should also be noted FIGS. 1-5, 6A-6E, 7, 8A-8B and 9-12 and its corresponding description in the present disclosure is not limited to dies and/or ICs. In some implementations, FIGS. 1-5, 6A-6E, 7, 8A-8B and 9-12 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a first substrate; a first integrated device coupled to the first substrate; a second substrate coupled to the first substrate through at least a plurality of solder interconnects, wherein the second substrate includes a plurality of interconnects comprising a first plurality of interconnects comprising a first plurality of via interconnects, wherein at least one via interconnect from the first plurality of via interconnects comprises a first width; and a second plurality of interconnects comprising a second plurality of via interconnects, wherein at least one via interconnect from the second plurality of via interconnects comprises a second width that is different from the first width; an encapsulation layer located between the first substrate and the second substrate; and a second integrated device coupled to the second substrate.

Aspect 2: The package of aspect 1, wherein the second width is greater than the first width.

Aspect 3: The package of aspects 1 through 2, wherein the first plurality of interconnects are configured to provide electrical paths for input/output (I/O) signals.

Aspect 4: The package of aspects 1 through 3, wherein the second plurality of interconnects are configured to provide electrical paths for ground.

Aspect 5: The package of aspects 1 through 4, wherein the second plurality of interconnects vertically overlap with the first integrated device and the second integrated device.

Aspect 6: The package of aspects 1 through 5, wherein the second integrated device is coupled to the second substrate through a plurality of solder interconnects.

Aspect 7: The package of aspect 6, wherein the plurality of solder interconnects comprise a first plurality of solder interconnects; and a second plurality of solder interconnects, wherein the second integrated device is coupled to the first plurality of interconnects of the second substrate through the first plurality of solder interconnects, and wherein the second integrated device is coupled to the second plurality of interconnects of the second substrate through the second plurality of solder interconnects.

Aspect 8: The package of aspects 1 through 7, wherein the second plurality of via interconnects comprises a set of via interconnects arranged in rows of via interconnects.

Aspect 9: The package of aspects 1 through 8, wherein the second plurality of via interconnects comprises a set of via interconnects arranged in staggered rows of via interconnects.

Aspect 10: The package of aspects 1 through 9, wherein at least one other via interconnect from the second plurality of via interconnects comprises a third width that is different from the first width and the second width.

Aspect 11: The package of aspect 10, wherein the third width is greater than the second width and the first width, and wherein the second width is greater than the first width.

Aspect 12: The package of aspects 1 through 11, wherein the first plurality of interconnects comprise a first plurality of pad interconnects coupled to the first plurality of via interconnects, and wherein the second plurality of interconnects comprise a second plurality of pad interconnects coupled to the second plurality of via interconnects.

Aspect 13: The package of aspect 12, wherein at least two solder interconnects are coupled to a pad interconnect from the second plurality of pad interconnects.

Aspect 14: The package of aspect 13, wherein only one solder interconnect is coupled to a pad interconnect from the first plurality of pad interconnects.

Aspect 15: The package of aspects 12 through 14, wherein a pad interconnect from the second plurality of pad interconnects comprises a square planar shape, a rectangular planar shape or a circular planar shape.

Aspect 16: The package of aspect 15, wherein a via interconnect from the second plurality of via interconnects comprises a square planar shape, a rectangular planar shape or a circular planar shape.

Aspect 17: The package of aspects 1 through 16, wherein a via interconnect from the second plurality of via interconnects comprises a square planar shape, a rectangular planar shape or a circular planar shape.

Aspect 18: The package of aspects 1 through 17, wherein the second substrate comprises a laminate substrate or an interposer.

Aspect 19: The package of aspects 1 through 18, wherein the second integrated device includes a memory die.

Aspect 20: The package of aspects 1 through 19, wherein the second integrated device is coupled to the second substrate through a plurality of solder interconnects and a plurality of core balls.

Aspect 21: The package of aspects 1 through 20, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a first substrate;
a first integrated device coupled to the first substrate;
a second substrate coupled to the first substrate through at least a plurality of solder interconnects, wherein the second substrate includes a plurality of interconnects comprising:
a first plurality of interconnects comprising a first plurality of via interconnects, wherein at least one via interconnect from the first plurality of via interconnects comprises a first width; and
a second plurality of interconnects comprising a second plurality of via interconnects, wherein at least one via interconnect from the second plurality of via interconnects comprises a second width that is different from the first width;
an encapsulation layer located between the first substrate and the second substrate; and
a second integrated device coupled to the second substrate.

2. The package of claim 1, wherein the second width is greater than the first width.

3. The package of claim 1, wherein the first plurality of interconnects are configured to provide electrical paths for input/output (I/O) signals.

4. The package of claim 1, wherein the second plurality of interconnects are configured to provide electrical paths for ground.

5. The package of claim 1, wherein the second plurality of interconnects vertically overlap with the first integrated device and the second integrated device.

6. The package of claim 1, wherein the second integrated device is coupled to the second substrate through a plurality of solder interconnects.

7. The package of claim 6,
wherein the plurality of solder interconnects comprise:
a first plurality of solder interconnects; and
a second plurality of solder interconnects,
wherein the second integrated device is coupled to the first plurality of interconnects of the second substrate through the first plurality of solder interconnects, and
wherein the second integrated device is coupled to the second plurality of interconnects of the second substrate through the second plurality of solder interconnects.

8. The package of claim 1, wherein the second plurality of via interconnects comprises a set of via interconnects arranged in rows of via interconnects.

9. The package of claim 1, wherein the second plurality of via interconnects comprises a set of via interconnects arranged in staggered rows of via interconnects.

10. The package of claim 1, wherein at least one other via interconnect from the second plurality of via interconnects comprises a third width that is different from the first width and the second width.

11. The package of claim 10,
wherein the third width is greater than the second width and the first width, and
wherein the second width is greater than the first width.

12. The package of claim 1,
wherein the first plurality of interconnects comprise a first plurality of pad interconnects coupled to the first plurality of via interconnects, and
wherein the second plurality of interconnects comprise a second plurality of pad interconnects coupled to the second plurality of via interconnects.

13. The package of claim 12, wherein at least two solder interconnects are coupled to a pad interconnect from the second plurality of pad interconnects.

14. The package of claim 13, wherein only one solder interconnect is coupled to a pad interconnect from the first plurality of pad interconnects.

15. The package of claim 12, wherein a pad interconnect from the second plurality of pad interconnects comprises a square planar shape, a rectangular planar shape or a circular planar shape.

16. The package of claim 15, wherein a via interconnect from the second plurality of via interconnects comprises a square planar shape, a rectangular planar shape or a circular planar shape.

17. The package of claim 1, wherein a via interconnect from the second plurality of via interconnects comprises a square planar shape, a rectangular planar shape or a circular planar shape.

18. The package of claim 1, wherein the second substrate comprises a laminate substrate or an interposer.

19. The package of claim 1, wherein the second integrated device includes a memory die.

20. The package of claim 1, wherein the second integrated device is coupled to the second substrate through a plurality of solder interconnects and a plurality of core balls.
